(19) United States
(12) Patent Application Publication
(10) Pub. No.: US 2002/0060356 A1
(43) Pub. Date: May 23, 2002

(54) Power semiconductor device

(75) Inventors: Hiroshi Nishibori, Fukuoka (JP); Masakazu Fukada, Tokyo (JP); Takanobu Yoshida, Fukuoka (JP); Naoki Yoshimatsu, Fukuoka (JP); Haruo Takao, Fukuoka (JP); Nobuyoshi Kimoto, Fukuoka (JP); Yasumi Uegai, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MITSUBISHI DENKI KABUSHIKI KAISHA, TOKYO (JP)

(21) Appl. No.: 09/845,272

(22) Filed: May 1, 2001

(30) Foreign Application Priority Data
Nov. 17, 2000 (JP) P2000-350571

(51) Int. Cl. H01L 23/495

(52) U.S. Cl. 257/668; 257/701; 257/703; 257/737

(57) ABSTRACT

It is an object to provide a power semiconductor device having a circuit pattern and a lower pattern made of an Al alloy for cost reduction and enabling reduction in heat resistance and improvement in resistance of a soldering layer to heat cycle. A substrate of semiconductor elements is mounted on a metal base plate made of a Cu alloy. The substrate of semiconductor elements includes an insulating substrate made of ceramics or the like. The circuit pattern and the lower pattern both made of an Al alloy are formed on an upper surface and a lower surface of the insulating substrate. The lower pattern is provided on an entire surface of the insulating substrate and joined onto the metal base plate through the soldering layer. Thicknesses of the metal base plate and the insulating substrate are respectively set to be 3.5 to 5.5 mm and 0.5 to 1 mm, for example. A thickness of the circuit pattern is set to be 0.4 to 0.6 mm and thicknesses of the lower pattern and the soldering layer are respectively set to be 0.2 mm or less and 100 to 300 μm.

### BACKGROUND OF THE INVENTION

1. Field of the Invention

The present invention is directed to a power semiconductor device. More particularly, it is directed to a power semiconductor device including an insulating substrate having an upper main surface for forming a circuit pattern and a lower main surface for forming a lower pattern that is joined onto a metal base plate by a jointing material.

2. Description of the Background Art

A lower pattern of a power semiconductor device has been conventionally used as a heat sink and heat dissipation has been performed by joining the lower pattern onto a metal base plate. An insulating substrate having the lower pattern and a circuit pattern formed on an upper main surface that is opposite to the lower pattern is made of ceramics and the like.

As materials for the circuit pattern and the lower pattern, a Cu (copper) alloy (containing Cu itself in the present specification and claims) and an Al (aluminum) alloy (containing Al itself in the present specification and claims) have been used. When an Al alloy is used, the circuit pattern and the lower pattern have been defined to have the same thickness of 0.4 mm and 0.5 mm, for example. A soldering layer for joining the lower pattern and the metal base plate under the insulating substrate has been defined to have an arbitrary thickness.

When a Cu alloy is used as the material for the circuit pattern and the lower pattern, cracks may be caused in the insulating substrate and the soldering layer with a high probability in an early stage due to a temperature cycle. As a countermeasure for this problem, Al/SiC and Cu/Mo having expansion coefficients more approximate to that of ceramics used as the material for the insulating substrate than that of Cu may be used as the materials for the metal base plate. While reliability of the power semiconductor device is improved by using Al/SiC and Cu/Mo, these materials have a disadvantage of being costly than a Cu alloy.

When an Al alloy is used as the material for the circuit pattern and the lower pattern, on the other hand, resistance of the insulating substrate made of ceramics to cracks can be improved. However, it is not expected to avoid cracks to be caused in the soldering layer in an early stage by this alternative. For this reason, Al/SiC and Cu/Mo are yet used as the materials for the metal base plate.

Especially, when the lower pattern is made of an Al alloy having a thickness of 0.4 to 0.5 mm, electrical resistance is increased as compared with the lower pattern made of a Cu alloy. The increase in electrical resistance results in increase in heat resistance of the power semiconductor device as a whole, to thereby reduce heat dissipation capacity of a semiconductor element to be mounted on the insulating substrate.

Further, as a thickness of the soldering layer is arbitrarily set, the soldering layer is defined to have a nonuniform thickness. Therefore, the insulating substrate may be inclined at a junction between the lower pattern and the metal base plate, inducing the heat resistance to increase. Consequently, it is probable that a balance between target heat resistance and resistance of the soldering layer to cracks may be lost, resulting in the problems of increased dispersion of a quality, change of design and decreased tolerance of design. A further problem may be caused that cracks due to a temperature cycle are likely to occur in the soldering layer at its corner portions of a thinned thickness in an early stage. This problem may result in increased heat resistance, to thereby destroy the power semiconductor element.

### SUMMARY OF THE INVENTION

A first aspect of the present invention is directed to a power semiconductor device, comprising: a ceramic substrate having a thickness of 0.5 to 1 mm; a circuit pattern made of an aluminum alloy and provided on an upper main surface of the ceramic substrate and having a thickness of 0.4 to 0.6 mm on which a power semiconductor element is held; a lower pattern made of the aluminum alloy having a thickness of 0.2 mm or less and provided entirely on a lower main surface of the ceramic substrate opposite to the upper main surface; a metal base plate made of a copper alloy having a thickness of 3.5 to 5.5 mm to be in opposite to the lower pattern; and a soldering layer having a thickness of 100 to 300 μm and provided between an entire surface of the lower pattern and the metal base plate for forming a joint therebetween.

A second aspect of the present invention is directed to a power semiconductor device, comprising: a ceramic substrate having a thickness of 0.5 to 1 mm; a circuit pattern made of an aluminum alloy and provided on an upper main surface of the ceramic substrate to grow to a thickness of 0.4 to 0.6 mm for holding a power semiconductor element thereon; a lower pattern formed of a metalized layer having a thickness of 0.1 mm or less and provided entirely on a lower main surface of the ceramic substrate opposite to the upper main surface; a metal base plate made of a copper alloy having a thickness of 3.5 to 5.5 mm to be opposite to the lower pattern; and a soldering layer having a thickness of 50 to 400 μm and provided between an entire surface of the lower pattern and the metal base plate for forming a joint therebetween.

According to a third aspect of the present invention, the power semiconductor device according to first or second aspect further comprises a wire bump provided on the lower pattern.

According to the first aspect of the present invention, it is possible to provide a power semiconductor device having excellence in heat dissipation capacity and heat cycle.

According to the second aspect of the present invention, as the lower pattern is formed of the metalized layer, the soldering layer as well as the lower pattern can be reduced in thickness. As a result, it is possible to provide an inexpensive power semiconductor device having excellence in heat dissipation capacity and productivity.

According to the third aspect of the present invention, it is possible to prevent the ceramic substrate from being inclined at a junction between the lower pattern and the metal base plate. Further, a space between the lower pattern and the metal base plate can be ensured. In addition, the thickness of the soldering layer is likely to be uniformalized, to enable the soldering layer to be easily reduced in thickness. As a result, excellence in productivity and considerably high effectiveness in cost reduction can be obtained.

It is an object of the present invention to provide a power semiconductor device having a circuit pattern and a lower pattern made of an Al alloy for cost reduction and enabling reduction in heat resistance and improvement in resistance of a soldering layer to heat cycle.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view illustrating a power semiconductor device to which the present invention is applicable:

FIG. 2 is a cross-sectional view showing thicknesses of members in a vicinity of a substrate 2 of semiconductor elements; and

FIG. 3 is a graph showing structures of the present invention.

### DESCRIPTION OF THE PREFERRED EMBODIMENTS

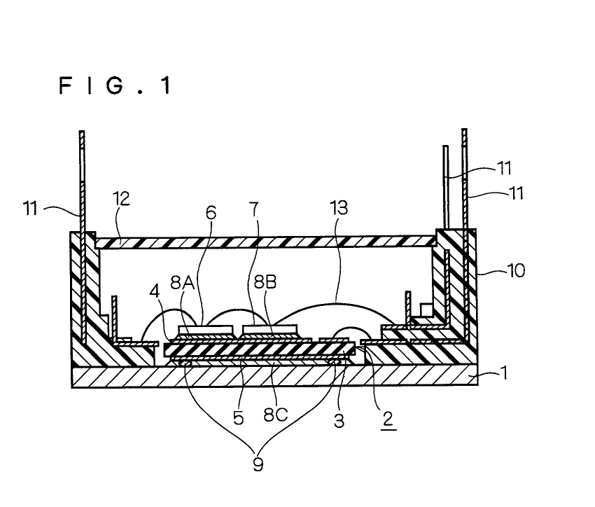

FIG. 1 is a cross-sectional view illustrating a power semiconductor device that is commonly applicable to preferred embodiments described later.

A substrate 2 of semiconductor elements is provided on a metal base plate 1 made of a Cu alloy. More particularly, the substrate 2 of semiconductor elements includes an insulating substrate 3 made of ceramics such as aluminum nitride (AlN) and alumina (Al₂O₃). The substrate 2 of semiconductor elements further includes a circuit pattern 4 and a lower pattern 5 joined onto an upper surface and a lower surface of the insulating substrate 3 using a brazing material or the like, respectively. Both of the circuit pattern 4 and the lower pattern 5 are made of an Al alloy. A thickness of the metal base plate 1 is set to be 3.5 to 5.5 mm, for example. A thickness of the insulating substrate 3 is set to be 0.5 to 1 mm, for example, and a thickness of the circuit pattern 4 is set to be 0.4 to 0.6 mm. The lower pattern 5 is provided on an entire surface of the insulating substrate 3.

A first semiconductor element 6 such as a power MOS transistor and a second semiconductor element 7 such as a free wheeling diode are provided on the circuit pattern 4 through a soldering layer 8A and a soldering layer 8B, respectively. The lower pattern 5 is joined onto the metal base plate 1 through a soldering layer 8C. The metal base plate 1 serves as a heat sink for the substrate 2 of semiconductor elements.

A case 10 surrounding the substrate 2 of semiconductor elements is provided on the metal base plate 1. A cover 12 is provided to the case 10 on a side opposite to the substrate 2 of semiconductor elements. Terminals 11 of main circuit contained in the case 10 are electrically connected to the first and second semiconductor elements 6 and 7 through an aluminum wire 13 for internal connection.

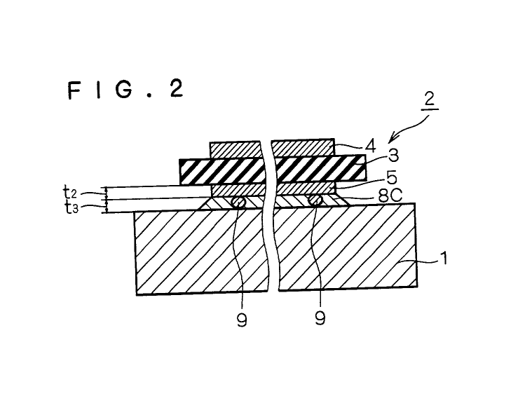

FIG. 2 is a cross-sectional view showing thicknesses of the members in a vicinity of the substrate 2 of semiconductor elements. In the present invention, thicknesses t₂ and t₃ refer to those of the lower pattern 5 and the soldering layer 8C, respectively.

First Preferred Embodiment

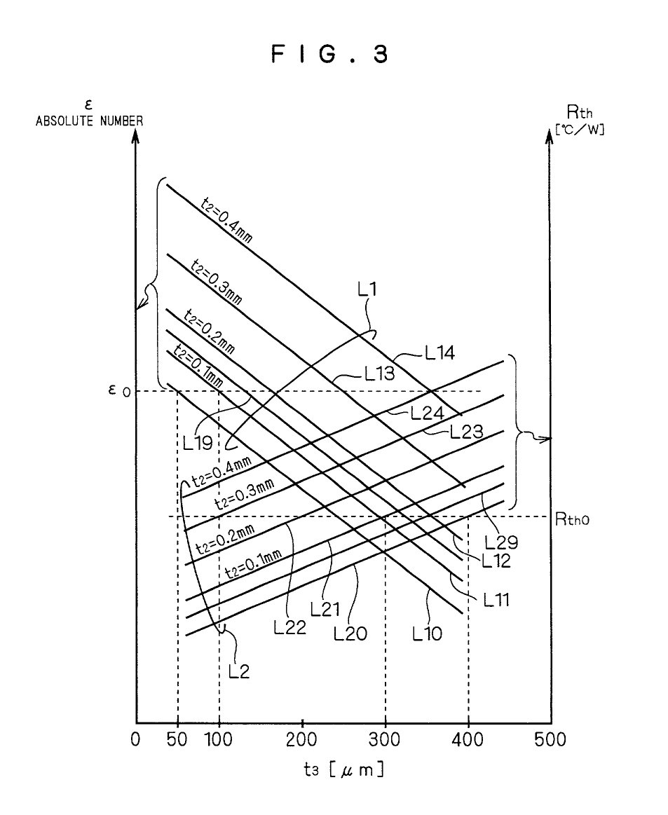

FIG. 3 is a graph showing structures of the present invention. A group of lines L1 refers to dependence of distortion ε (absolute number) to occur in the soldering layer 8C due to a heat cycle and a group of lines L2 refers to dependence of heat resistance Rₜₕ, (° C./W), both on the thickness t₃ of the soldering layer 8C.

A heat cycle requires temperature ranging from −40 to 125° C. The target number of times of heat cycles is 1000 to 1500 cycles in power modules for electric railways and automobiles requiring high reliability.

In the group of lines L1, line L11, line L12, line L13 and line L14 show the selection of the thickness t₂ of the lower pattern 5 of 0.1 mm, 0.2 mm, 0.3 mm and 0.4 mm, respectively. In the group of lines L2, line L21, line L22, line L23 and line L24 show the selection of the thickness t₂ of the lower pattern 5 of 0.1 mm, 0.2 mm, 0.3 mm and 0.4 mm, respectively. When Al foil is joined as the lower pattern 5 on the insulating substrate 3 made of ceramics, a lower limit of the thickness t₂ may be around 0.1 mm. There occurs little fluctuation in lines L11, L12, L13, L14, L21, L22, L23 and L24 by the thicknesses of the metal base plate 1, the insulating substrate 3 and the circuit pattern 4 falling within the ranges thereof as mentioned above. For comparison, line L19 and line L29 defined by the circuit pattern 4 and the lower pattern 5 made of a Cu alloy are added to the group of lines L1 and L2, respectively. More particularly, the circuit pattern 4 grows to a thickness of 0.3 mm and the lower pattern 5 grows to a thickness of 0.15 mm.

As the thickness t₃ of the soldering layer 8C increases and as the thickness t₂ of the lower pattern 5 decreases, the distortion ε to occur in the soldering layer 8C is reduced. In order to obtain the distortion ε that is smaller than the distortion occurring in the case using a Cu alloy as the circuit pattern 4 and the lower pattern 5 (line L19), the thickness t₂ is desired to be 0.1 mm (line L11) when an Al alloy is used as the lower pattern 5. However, in order to obtain the distortion ε to occur in the soldering layer 8C having a value smaller than a permissible value ε₀, the thickness t₃ of the soldering layer 8C is required to be 100 μm or more when the thickness t₂ of the lower pattern 5 is 0.1 mm.

As the thickness t₃ of the soldering layer 8C decreases and the thickness t₂ of the lower pattern 5 decreases, the heat resistance Rₜₕ is reduced. The thickness t₂ of the lower pattern 5 is desired to be 0.1 mm (line L21) when an Al alloy is used as the same, though heat resistance smaller than that in the case using a Cu alloy as the circuit pattern 4 and the lower pattern 5 (line L29) cannot be obtained. However, in order to obtain the heat resistance Rₜₕ having a value smaller than a permissible value Rₜₕ₀, the thickness t₃ of the soldering layer 8C is desired to be 300 μm or less even when the thickness t₂ of the lower pattern 5 is 0.1 mm (line L21). On the other hand, even when the thickness t₂ of the lower pattern 5 is 0.2 mm (line L12), the distortion ε to occur in the soldering layer 8C will have a value smaller than the permissible value ε₀ under the condition that the thickness t₃ of the soldering layer 8C is 300 μm.

In view of the foregoing, when both of the circuit pattern 4 and the lower pattern 5 are made of an Al alloy and when the thicknesses of the metal base plate 1, the insulating substrate 3 and the circuit pattern 4 fall within the ranges as mentioned above, for example, the thickness t₃ of the soldering layer 8C is set to fall within the range of 100 to 300 μm with the lower pattern 5 having the thickness t₂ of 0.2 mm or less to thereby control the distortion ε and the heat resistance Rₜₕ favorably. Therefore, a power semiconductor device having excellence in heat dissipation capacity and heat cycle can be provided. Further, the metal base plate 1 can be made of an inexpensive Cu alloy instead of costly Al/SiC and Cu/Mo.

It is a matter of course that the customary advantages of using an Al alloy as the circuit pattern 4 and the lower pattern 5 can be expected to be comparable with the case using a Cu alloy instead. That is, stress to be imposed on the insulating substrate 3 is reduced resulted from small moduli of elasticity of an Al alloy. Further, even when the first and second semiconductor elements 6 and 7 are joined with the soldering layers 8A and 8B to be mounted on the circuit pattern 4, splash of solder is unlikely to adhere. Both of these advantages can be obtained here.

Second Preferred Embodiment

Both of line L10 belonging to the group of lines L1 and line L20 belonging to the group of lines L2 are defined by the lower pattern 5 formed of a metalized layer. There occurs little fluctuation in lines L10 and L20 by the thicknesses of the metal base pate 1, the insulating substrate 3 and the circuit pattern 4 under the condition that these thicknesses fall within the ranges thereof as mentioned above. Such metalized layer is formed using known metalizing techniques such as spraying or vapor deposition to grow to a thickness of 0.005 to 0.1 mm, or preferably, 0.020 mm or less. As materials for the metalized layer, Mo—Mn (molybdenum-manganese) and W (tungsten) are applicable. Alternatively, a brazing material such as an Al-based material to be provided between the circuit pattern 4 and the insulating substrate 3 is applicable. In any case, in order to improve adhesion and wettability to the soldering layer 8C, it is desirable to plate the surface of the metalized layer, namely, the side to be joined onto the metal base plate 1, with Ni (nickel) plating.

The thickness of the lower pattern 5 can be considerably small accordingly by using the metalized layer as the same. Therefore, the thickness t₃ of the soldering layer 8C can be selected within an extended range. More particularly, when the thicknesses of the metal base plate 1, the insulating substrate 3 and the circuit pattern 4 fall within the ranges thereof as mentioned above, for example, the value of the distortion ε to occur in the soldering layer 8C can be made smaller than the permissible value ε₀ under the condition that the thickness t₃ of the soldering layer 8C is 50 μm or more. Further, the value of the heat resistance Rₜₕ can be made smaller than the permissible value Rₜₕ₀ under the condition that the thickness t₃ of the soldering layer 8C is 400 μm or less. That is, the thickness t₃ of the soldering layer 8C can be set within the range of 50 to 400 μm.

In view of the foregoing, the thickness of the soldering layer 8C can be small as well according to this preferred embodiment. As a result, it is possible to provide an inexpensive power semiconductor device having excellence in heat dissipation capacity and productivity.

Third Preferred Embodiment

As shown in FIGS. 1 and 2, wire bumps 9 made of Al or the like are sandwiched between the lower pattern 5 and the metal base plate 1 to be in contact with the soldering layer 8C. A space between the metal base plate 1 and the substrate 2 of semiconductor elements can be uniformalized by these wire bumps 9.

The insulating substrate 3 can be thereby prevented from being inclined at a junction between the lower pattern 5 and the metal base plate 1. Further, a space between the lower pattern 5 and the metal base plate 1 can be ensured. In addition, the thickness of the soldering layer 8C is likely to be uniformalized, to enable the soldering layer 8C to be easily reduced in thickness. As a result, excellence in productivity and considerably high effectiveness in cost reduction can be obtained.

In consideration of heat dissipation capacity and reliability, diameters of the wire bumps 9 are desirably about 50 to 400 μm. Consequently, it is a matter of course that the wire bumps 9 are further applicable to the aforementioned first and second preferred embodiments.

While the invention has been shown and described in detail, the foregoing description is in all aspects illustrative and not restrictive. It is therefore understood that numerous modifications and variations can be devised without departing from the scope of the invention.

What is claimed is:

1. A power semiconductor device comprising:
a ceramic substrate having a thickness of 0.5 to 1 mm;
a power semiconductor element;
a circuit pattern made of an aluminum alloy and provided on an upper main surface of said ceramic substrate and having a thickness of 0.4 to 0.6 mm on which said power semiconductor element is held;
a lower pattern made of said aluminum alloy and provided entirely on a lower main surface of said ceramic substrate opposite to said upper main surface;
a metal base plate made of a copper alloy having a thickness of 3.5 to 5.5 mm to be opposite to said lower pattern; and
a soldering layer provided between an entire surface of said lower pattern and said metal base plate for forming a joint therebetween.

2. The power semiconductor device according to claim 1, wherein a thickness of said lower pattern is 0.2 mm or less.

3. The power semiconductor device according to claim 2, wherein a thickness of said soldering layer is 100 to 300 μm.

4. The power semiconductor device according to claim 3, further comprising a wire bump provided on said lower pattern.

5. The power semiconductor device according to claim 1, wherein a thickness of said lower pattern is 0.1 mm or less.

6. The power semiconductor device according to claim 5, wherein a thickness of said soldering layer is 50 to 400 μm.

7. The power semiconductor device according to claim 6, further comprising a wire bump provided on said lower pattern.
